(19) United States
(12) Patent Application Publication
(10) Pub. No.: US 2010/0117055 A1
(43) Pub. Date: May 13, 2010

(54) SEMICONDUCTOR LIGHT-EMITTING DEVICE AND METHOD FOR MANUFACTURING SEMICONDUCTOR LIGHT-EMITTING DEVICE

(75) Inventors: Yasuo Nakanishi, Kyoto (JP); Shunji Nakata, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto-fu (JP)

(21) Appl. No.: 12/452,044

(22) PCT Filed: May 12, 2008
(86) PCT No.: PCT/JP2008/058717

§ 371 Date: Dec. 14, 2009

(30) Foreign Application Priority Data
Jun. 15, 2007 (JP) 2007-158525
Jun. 15, 2007 (JP) 2007-158535
Jan. 18, 2008 (JP) 2008-009341
Jan. 18, 2008 (JP) 2008-009344

(51) Int. Cl. H01L 33/00; H01L 21/20

(52) U.S. Cl. 257/13; 438/46; 257/E33.023; 257/E33.008; 257/E21.09

(57) ABSTRACT

To provide a semiconductor light-emitting device capable of sufficiently emitting lights of different colors.

A semiconductor light-emitting device (1) includes a substrate (2) and a semiconductor layer (3) formed on the substrate (2). The semiconductor layer (3) has a buffer layer (11), an n-type semiconductor layer (12), a light-emitting layer (13), and a p-type semiconductor layer (14) stacked in this order from a substrate (2)-side. The light-emitting layer (13) has an MQW structure in which a plurality of well layers (21ₙ) and a plurality of barrier layers (22ₘ) are alternately stacked. A well layer (21₁) closest to the p-type semiconductor layer (14) emits a blue light having a wavelength of about 420 nm to about 470 nm. The well layer (21₁) is made of an undoped Inₓ₁Ga₁₋ₓ₁N (0.05≦X₁<0.2). A well layer (21₂) second closest to the p-type semiconductor layer (14) emits a green light having a wavelength of about 520 nm to about 650 nm. The well layer 21₂ is made of undoped Inₓ₂Ga₁₋ₓ₂N (0.2≦X₂≦0.3).

### TECHNICAL FIELD

The present invention relates to a semiconductor light-emitting device that can emit at least two different colors, that is, lights having two different wavelengths, respectively and a method for manufacturing a semiconductor light-emitting device.

### BACKGROUND ART

There are conventionally known a semiconductor light-emitting device that can emit a plurality of (such as two) lights of different colors and a method for manufacturing a semiconductor light-emitting device.

For example, Patent Document 1 discloses a semiconductor light-emitting device having an n-type semiconductor layer, a light-emitting layer, and a p-type semiconductor layer stacked in this order from a substrate-side. Furthermore, the light-emitting layer of the semiconductor light-emitting device includes a red light-emitting layer that can emit a red light and a blue light-emitting layer that can emit a blue light. This light-emitting layer has the red light-emitting layer and the blue light-emitting layer stacked in this order from the substrate-side. Each of the red light-emitting layer and the blue light-emitting layer has an MQW (multiple quantum well) structure including a plurality of well layers made of InGaN. Furthermore, the well layers constituting the blue light-emitting layer are constituted such that an In ratio in InGaN constituting each well layer is lower than that in InGaN constituting each well layer of the red light-emitting layer. By this configuration, the semiconductor light-emitting device emits lights of different colors by changing magnitudes of band gaps of the well layers of the respective light-emitting layers.

When a current is supplied to the semiconductor light-emitting device described in Patent Document 1, electrons are injected into the respective light-emitting layers via the n-type semiconductor layer and holes are injected into the respective light-emitting layers via the p-type semiconductor layer. It is considered that the well layers of the red light-emitting layer emit the red light by recombination of electrons and holes, and that those of the blue light-emitting layer emit the blue light by recombination of electrons and holes.

### [Patent Document 1] Japanese Patent Application Laid-open No. 2005-217386

### DISCLOSURE OF THE INVENTION

### Problems to be Solved by the Invention

In the semiconductor light-emitting device described in Patent Document 1, the electrons having high mobility can reach the well layers of the respective light-emitting layers after passing through the n-type semiconductor layer since each light-emitting layer includes a plurality of well layers. The holes having low mobility can reach the well layers of the blue light-emitting layer on a p-type semiconductor layer-side to some extent after passing through the p-type semiconductor layer. However, the holes can hardly reach the well layers of the red light-emitting layer far from the p-type semiconductor layer. Accordingly, the semiconductor light-emitting device described in Patent Document 1 has problems such that, although the blue light-emitting layer closer to the p-type semiconductor layer can emit a blue light by recombination of electrons and holes, the red light-emitting layer far from the p-type semiconductor layer can hardly emit a red light since recombination of electrons and holes hardly occurs in the red light-emitting layer.

Further, the semiconductor light-emitting device described in Patent Document 1 has the following problem. The different well layers emit lights of different colors by changing only In ratios in InGaN constituting the respective well layers. However, to change the In ratios, it is required to change a growth temperature or change a flow rate of In material gas in a manufacturing process. However, it is quite difficult to control the growth temperature or the flow rate of the In material gas, and therefore it is quite difficult to generate InGaN having a desired In ratio by controlling the growth temperature or the flow rate. Due to this, it is difficult to manufacture a semiconductor light-emitting device that can emit lights having desired wavelengths only by the In ratios.

The present invention has been contrived to solve the above problems, and an object of the present invention is to provide a semiconductor light-emitting device that can sufficiently emit lights of different colors and a method for manufacturing a semiconductor light-emitting device.

The present invention has been contrived to solve the above problems, and an object of the present invention is to provide a semiconductor light-emitting device that can easily control wavelengths of lights to be emitted and a method for manufacturing a semiconductor light-emitting device.

### Means for Solving the Problems

To achieve the objects, the invention according to claim 1 is a semiconductor light-emitting device including: a p-type semiconductor layer; and a light-emitting layer including a plurality of well layers made of an InGaN-based semiconductor and a barrier layer made of a GaN-based semiconductor and formed between the respective well layers, wherein an In ratio X₁ in an Inₓ₁Ga₁₋ₓ₁N-based semiconductor including a first well layer closest to the p-type semiconductor layer differs from an In ratio X₂ in an Inₓ₂Ga₁₋ₓ₂N-based semiconductor including a second well layer second closest to the p-type semiconductor layer.

The invention according to claim 2 is the semiconductor light-emitting device according to claim 1, wherein the In ratio X₁ is lower than the In ratio X₂.

The invention according to claim 3 is the semiconductor light-emitting device according to claim 1, wherein the In ratio X₁ satisfies X₁<0.2 and the In ratio X₂ satisfies X₂≧0.2.

The invention according to claim 4 is the semiconductor light-emitting device according to claim 1, wherein a barrier layer between the first well layer and the second well layer has a thickness enough to be able to transmit a light emitted from the second well layer.

The invention according to claim 5 is the semiconductor light-emitting device according to claim 1, wherein a barrier layer between the first well layer and the second well layer has a thickness equal to or smaller than 20 nm.

The invention according to claim 6 is the semiconductor light-emitting device according to claim 1, wherein the first well layer emits a blue light and the second well layer emits a light having a peak between a green light and a yellow light.

The invention according to claim 7 is the semiconductor light-emitting device according to claim 1, wherein a thickness of the first well layer is smaller than a thickness of the second well layer and smaller than a thickness enough to produce a quantum-size affect.

The invention according to claim 8 is a semiconductor light-emitting device including: a p-type semiconductor layer; and a light-emitting layer including a plurality of well layers made of an InGaN-based semiconductor and a barrier layer made of a GaN-based semiconductor and formed between the respective well layers, wherein an In ratio X₁ in an Inₓ₁Ga₁₋ₓ₁N-based semiconductor including a first well layer closest to the p-type semiconductor layer satisfies 0.05≦X₁<0.2, an In ratio X₂ in an Inₓ₂Ga₁₋ₓ₂N-based semiconductor including a second well layer second closest to the p-type semiconductor layer satisfies 0.2≦X₂≦0.3, and a thickness of a barrier layer between the first well layer and the second well layer is 12 nm to 16 nm.

The invention of claim 9 is a method for manufacturing a semiconductor light-emitting device including: a p-type semiconductor layer made of a p-type GaN-based semiconductor; and a light-emitting layer including a plurality of well layers made of an InGaN-based semiconductor, wherein an In ratio X₁ in an Inₓ₁Ga₁₋ₓ₁N-based semiconductor including a first well layer closest to the p-type semiconductor layer differs from an In ratio X₂ in an Inₓ₂Ga₁₋ₓ₂N-based semiconductor including a second well layer second closest to the p-type semiconductor layer, the method comprising: a light-emitting layer forming step of forming a light-emitting, layer including the first well layer and the second well layer; and a p-type semiconductor layer forming step of growing the p-type semiconductor layer at a growth temperature equal to or lower than 850° C. after the light-emitting layer forming step.

The invention according to claim 10 is a semiconductor light-emitting device including: a p-type semiconductor layer; and a light-emitting layer including a plurality of well layers made of an InGaN-based semiconductor and a barrier layer formed between the respective well layers, wherein

the light-emitting layer includes a first well layer and a second well layer thicker than the first well layer and emits a light having a wavelength different from a wavelength of a light emitted from the first well layer, the first well layer is arranged at a closer position to the p-type semiconductor layer than the second well layer, a barrier layer between the first well layer and the second well layer is constituted to have a thickness enough to be able to transmit a light emitted from the second well layer.

The invention according to claim 11 is the semiconductor light-emitting device according to claim 10, wherein the first well layer is constituted to have a thickness enough to produce a quantum size effect.

The “thickness enough to produce a quantum size effect” means a thickness equal to or smaller than a wavelength of an electron or, to be specific, equal to or smaller than about 10 nm.

The invention according to claim 12 is the semiconductor light-emitting device according to claim 10, wherein the thickness of the barrier layer between the first well layer and the second well layer is 12 nm to 16 nm.

The invention according to claim 13 is the semiconductor light-emitting device according to claim 10, wherein the first well layer is formed at a closest position to the p-type semiconductor layer among the well layers, and the second well layer is formed at a second closest position to the p-type semiconductor layer among the well layers.

The invention according to claim 14 is the semiconductor light-emitting device according to claim 10, wherein the first well layer emits a shorter-wavelength light than the light emitted from the second well layer.

The invention according to claim 15 is the semiconductor light-emitting device according to claim 10, wherein the second well layer is higher in an In ratio in the InGaN-based semiconductor than the first well layer.

The invention according to claim 16 is the semiconductor light-emitting device according to claim 10, wherein the first well layer emits a blue light and the second well layer emits a light having a peak between a green light and a yellow light.

The invention according to claim 17 is a semiconductor light-emitting device including: a p-type semiconductor layer; and a light-emitting layer including a plurality of well layers made of an InGaN-based semiconductor and a barrier layer made of a GaN-based semiconductor and formed between the respective well layers, wherein a thickness d₁ of a first well layer closest to the p-type semiconductor layer satisfies 2 nm≦d₁3 nm, a thickness d₂ of a second well layer second closest to the p-type semiconductor layer satisfies 3 nm≦d₁10 nm, and a thickness of a barrier layer between the first well layer and the second well layer is 12 nm to 16 nm.

The invention according to claim 18 is a method for manufacturing a semiconductor light-emitting device including: a p-type semiconductor layer made of a p-type GaN-based semiconductor; and a light-emitting layer including a plurality of well layers including a first well layer made of an InGaN-based semiconductor and a second well layer thicker than the first well layer, and a barrier layer capable of transmitting a light emitted from the second well layer, the method including: a light-emitting layer forming step of forming the light-emitting layer including the first well layer and the second well layer; and a p-type semiconductor layer forming step of growing the p-type semiconductor layer at a growth temperature equal to or lower than 850° C. after the light-emitting layer forming step.

### EFFECTS OF THE INVENTION

According to the present invention, the In ratio X₁ in the first well layer made of an InGaN-based semiconductor is set different from the In ratio X₂ in the second well layer made of an InGaN-based semiconductor. By so configuring the first well layer and the second well layer that holes can easily reach, lights of two different colors can be sufficiently emitted.

According to the present invention, the second well layer is formed thicker than the first well layer, and therefore a wavelength of the light emitted from the first well layer can be set smaller than that of the light emitted from the second well layer. In this way, the present invention can easily control the wavelengths of two or more lights since the wavelengths of the emitted lights are controlled not only by the In ratios in the InGaN but also the thicknesses of the well layers easily controllable in the manufacturing process. Furthermore, the present invention can control tint relatively easily by changing thicknesses of the well layers and the barrier layers.

### BRIEF DESCRIPTION OF THE DRAWINGS

FIG. 1 A cross-sectional view of a semiconductor light-emitting device according to a first embodiment of the present invention.

FIG. 2 A cross-sectional view of a light-emitting layer of the semiconductor light-emitting device.

FIG. 3 An energy band diagram near the light-emitting layer.

FIG. 4 A cross-sectional view of a light-emitting layer according to a second embodiment.

FIG. 5 A graph showing a comparison of emission spectrums when a thickness of a barrier layer is changed.

FIG. 6 A chart showing a comparison of relative intensity ratios when a thickness of a barrier layer is changed.

FIG. 7 A graph showing an EL intensity spectrum when a p-type semiconductor layer is formed at a growth temperature of about 1010° C.

FIG. 8 A graph showing an EL intensity spectrum when a p-type semiconductor layer is formed at a growth temperature of about 850° C.

### EXPLANATIONS OF REFERENCE NUMERALS

1 Semiconductor light-emitting device
2 Substrate
3 Semiconductor layer
4 n-side electrode
5 p-side electrode.
11 Buffer layer
12 n-type semiconductor layer
13 Light-emitting layer
14 p-type semiconductor layer
21ₙ Well layer
22ₘ Barrier layer
21₁ First well layer
21₂ Second well layer
L_{b} Blue light
L_{g} Green light
X₁ In ratio
X₂ In ratio

### BEST MODE FOR CARRYING OUT THE INVENTION

### First Embodiment

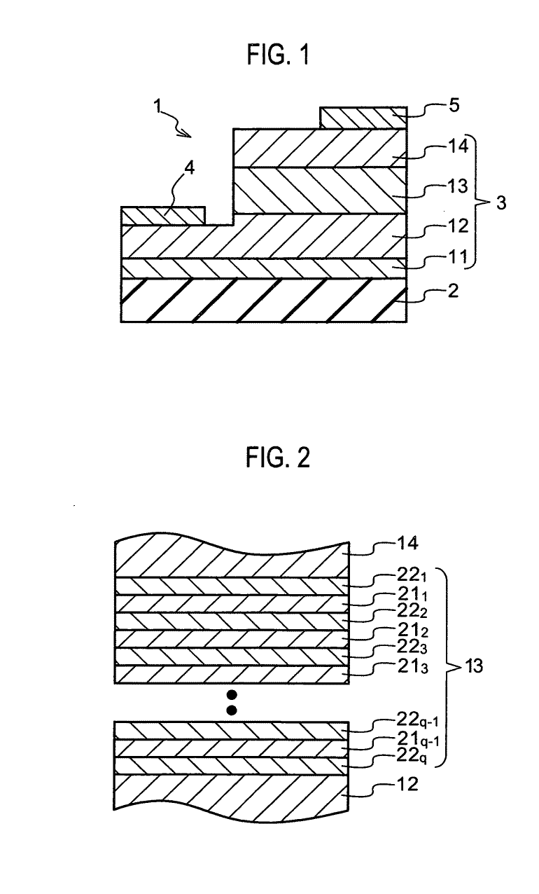

A semiconductor light-emitting device according to a first embodiment of the present invention is described below with reference to the drawings. FIG. 1 is a cross-sectional view of a semiconductor light-emitting device according to an embodiment of the present invention. FIG. 2 is a cross-sectional view of a light-emitting layer of the semiconductor light-emitting device.

As shown in FIG. 1, the semiconductor light-emitting device 1 according to the first embodiment includes a substrate 2, a semiconductor layer 3 formed on the substrate 2, an n-side electrode 4, and a p-side electrode 5.

The substrate 2 is constituted by a sapphire (Al₂O₃) substrate.

The semiconductor layer 3 has a buffer layer 11, an n-type semiconductor layer 12, a light-emitting layer 13, and a p-type semiconductor layer 14 stacked in this order from a substrate 2-side.

The buffer layer 11 is made of AlN having a thickness of about 10 angstroms to about 50 angstroms.

The n-type semiconductor layer 12 is made of n-type GaN having a thickness of about 4 μm and doped with Si having a concentration of about 3×10¹⁸ cm⁻³. The light-emitting layer 13 and the p-type semiconductor layer 14 are partially etched so as to expose a part of an upper surface of the n-type semiconductor layer 12.

As shown in FIG. 2, the light-emitting layer 13 has an MQW (Multi Quantum Well) structure in which a plurality of well layers 21ₙ (n=1, 2, . . . q−1) and a plurality of barrier layers 22ₘ (m=1, 2, . . . q) are alternately stacked by as much as six to eleven pairs, preferably by as much as eight pairs.

The well layers 21ₙ are made of undoped InGaN having an equal thickness of about 2 nm to 3 nm, preferably about 2.8 nm.

Note that the well layer (corresponding to a first well layer in claim 1) 21₁ closest to the p-type semiconductor layer 14 is a layer for emitting a blue light having a wavelength of about 420 nm to about 470 nm. The well layer 21₁ is made of undoped Inₓ₁Ga₁₋ₓ₁N. The well layer 21₁ is constituted such that an In ratio X₁ in the InGaN constituting the well layer 21₁ satisfies 0.05≦X₁<0.2.

The well layer (corresponding to a second well layer in claim 1) 21₂ second closest to the p-type semiconductor layer 14 is a layer for emitting a green light (or a yellow light) having a wavelength of about 520 nm to about 650 nm. The well layer 21₂ is made of undoped Inₓ₂Ga₁₋ₓ₂N. The well layer 21₂ is constituted such that an In ratio X₂ in the InGaN constituting the well layer 21₂ satisfies 0.2≦X₂0.3. The other well layers 21ₙ (3≦n≦q−1) are made of InGaN equal in the ratio and thickness to the well layer 21₂.

Each barrier layer 22ₘ is formed between the well layers 21ₙ. Each barrier layer 22ₘ is made of undoped GaN having a thickness equal to or smaller than about 20 nm, preferably equal to or smaller than about 16 nm.

The p-type semiconductor layer 14 is made of p-type GaN having a thickness of about 200 nm and doped with Mg having a concentration of about 3×10¹⁹ cm⁻³.

The n-side electrode 4 has a stacked structure having a thickness of about 2500 nm and having Al, Ti, Pt, and Au. The n-side electrode 4 is ohmic-connected to the exposed upper surface of the n-type semiconductor layer 12.

The p-side electrode 5 has a stacked structure having a thickness of about 3000 nm and having Ti and Al. The p-side electrode 5 is ohmic-connected to an upper surface of the p-type semiconductor layer 14.

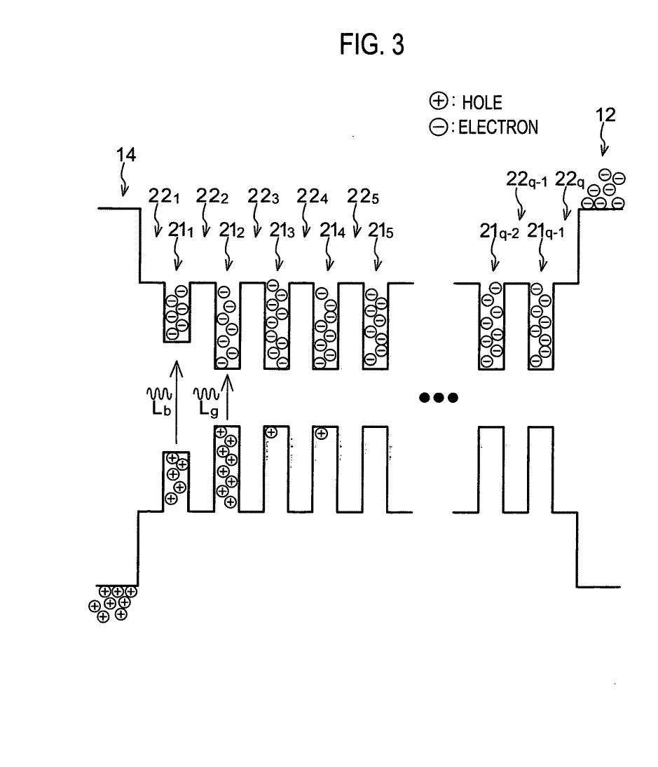

An operation performed by the semiconductor light-emitting device 1 is described next. FIG. 3 is an energy band diagram near the light-emitting layer.

First, when a forward voltage is applied to between the n-side electrode 4 and the p-side electrode 5, electrons are injected from the n-side electrode 4 into the semiconductor layer 3, and holes are injected from the p-side electrode 5 into the semiconductor layer 3. As shown in FIG. 3, the electrons injected from the n-side electrode 4 into the n-type semiconductor layer 12 can reach even each well layer 21₁ farthest from the n-type semiconductor layer 12 because of high mobility. On the other hand, the holes injected from the p-side electrode 5 into the p-type semiconductor layer 14 are low in mobility. Therefore, most of the holes are trapped in the well layers 21₁ and 21₂ closer to the p-type semiconductor layer 14.

As a result, recombination of electrons and holes is sufficiently carried out in the well layer 21₁ where the electrons and holes are sufficiently trapped, and then the well layer 21₁ emits a blue light L_{b}. The blue light L_{b} emitted from the well layer 21₁ transmits through a barrier layer 22₁ and the p-type semiconductor layer 14 and then irradiated to the outside.

Recombination of electrons and holes is sufficiently carried out in the well layer 21₂ where the electrons and holes are sufficiently trapped, and then the well layer 21₂ emits a green light L_{g}. The green light L_{g} emitted from the well layer 21₂ transmits through the thin barrier layers 22₁ and 22₂ each having a thickness equal to or smaller than about 20 nm. The green light L_{g} having transmitted the barrier layers 22₁ and 22₂ transmits through the p-type semiconductor layer 14 and then irradiated to the outside.

On the other hand, the well layers 21ₙ (3≦n) far from the p-type semiconductor layer 14 do not emit the green light L_{g} so much, since the holes are hardly trapped in the well layers 21ₙ (3≦n).

As a result, the blue light L_{b} and the green light L_{g} are sufficiently irradiated from the semiconductor light-emitting device 1 to the outside.

A method for manufacturing the semiconductor light-emitting device 1 described above is explained next.

First, the substrate 2 constituted by a sapphire substrate is introduced into an MOCVD device (not shown). In a state of setting a growth temperature to about 900° C. to about 1100° C., trimethylaluminum gas (hereinafter, TMA) and ammonium gas are supplied using carrier gas, thereby forming the buffer layer 11 made of AlN on the substrate 2.

Next, in a state of setting the growth temperature to about 1050° C., silan gas, trimethylgallium gas (hereinafter TMG), and the ammonium gas are supplied using carrier gas, thereby forming the n-type semiconductor layer 12 made of n-type GaN doped with Si on the buffer layer 11.

Next, in a state of setting the growth temperature to about 690° C., the TMG gas and ammonium gas are supplied using carrier gas, thereby forming the barrier layer 22_{q} made of undoped GaN on the n-type semiconductor layer 12. Thereafter, in a state of keeping the growth temperature to about 690° C., trimethylindium (hereinafter, TMI) gas, the TMG gas, and the ammonium gas are supplied using carrier gas, thereby forming the well layer 21_{q-1} made of undoped Inₓ₂Ga₁₋ₓ₂N (0.2≦X₂≦0.3) on the barrier layer 22_{q}. Thereafter, the barrier layer 22₂ to the well layer 21₂ and the barrier layer 22ₘ to the well layer 21ₙ are alternately formed under the same conditions.

Next, to improve the In ratio in the IgGaN, in a state of raising the growth temperature to about 760° C., the TMI gas, the TMG gas, and the ammonium gas are supplied using carrier gas, thereby forming the well layer 21₁ made of undoped Inₓ₁Ga₁₋ₓ₁N (0.05≦X₁<0.2). Finally, in a state of setting the growth temperature to about 760° C., the TMG gas and the ammonium gas are supplied using carrier gas, thereby forming the barrier layer 22₁ made of undoped GaN. The light-emitting layer 13 is thereby completed.

Next, in a state of setting the growth temperature to be equal to or lower than about 850° C., bis(cyclopentadienyl)magnesium (Cp₂Mg) gas, the TMG gas, and the ammonium gas are supplied, thereby forming the p-type semiconductor layer 14 made of p-type GaN doped with Mg on the light-emitting layer 13. Note that a flow rate of the ammonium gas is set to be equal to or higher than about 10 SLM higher than an ordinary flow rate (such as about 4.0 SLM), so as to grow the p-type semiconductor layer 14 made of p-type GaN at a low temperature of about 850° C.

Next, the p-type semiconductor layer 14 and the light-emitting layer 13 are partially etched so as to expose a part of the upper surface of the n-type semiconductor layer 12. Thereafter, the n-side electrode 4 and the p-side electrode 5 are formed. Finally, the resultant element is divided into devices, thereby completing the semiconductor light-emitting device 1.

As described above, in the semiconductor light-emitting device 1 according to the first embodiment, the In ratio X₁ of the well layer 21₁ closest to the p-type semiconductor layer 14 is set different from the In ratio X₂ of the well layer 21₂ second closest to the p-type semiconductor layer 14. In this way, by changing the In ratios X₁ and X₂ of the two well layers 21₁ and 21₂ that even the holes having the low mobility can reach, it is possible to sufficiently emit lights (a blue light and a green light) having different wavelengths.

Furthermore, in the semiconductor light-emitting device 1 according to the first embodiment, the well layer 21₁ having the low In ratio X₁ and a wide band gap is formed to be closer to the p-type semiconductor layer 14, that is, closer to the side to which holes are supplied than the well layer 21₂. In this way, by forming the well layer 21₁ where it is difficult to trap the holes to be closer to the p-type semiconductor layer 14, the number of holes reaching up to the well layer 21₂ can be further increased, and thus an emission intensity in the well layer 21₂ can be further improved.

Further, in the semiconductor light-emitting device 1 according to the first embodiment, the barrier layer 22₂ between the well layers 21₁ and 21₂ is constituted to have the thickness equal to or smaller than about 20 nm, preferably equal to or smaller than about 16 nm at which thickness the barrier layer 22₂ can transmit the green light emitted from the well layer 21₂. The green light can be thereby irradiated to the outside.

Further, in the semiconductor light-emitting device 1 according to the first embodiment, the growth temperature of the p-type semiconductor layer 14 is set to be equal to or lower than about 850° C. By this configuration, degradation in crystallinity of the InGaN constituting the well layers 21ₙ, particularly the well layers 21ₙ (n≧2) that emit the green light can be suppressed at the time of forming the p-type semiconductor layer 14. Therefore, it is possible to irradiate more green lights to the outside.

Further, the semiconductor light-emitting device 1 according to the first embodiment can emit lights of two different colors without using a fluorescent body for which it is difficult to control an addition amount and which tends to be degraded. Therefore, it is possible to easily control light amounts of the lights of different colors to suppress tint irregularities, and suppress degradation to ensure high reliability. Also, it is possible to realize an intermediate color (a pastel color) that cannot expressed by the fluorescent body.

### Second Embodiment

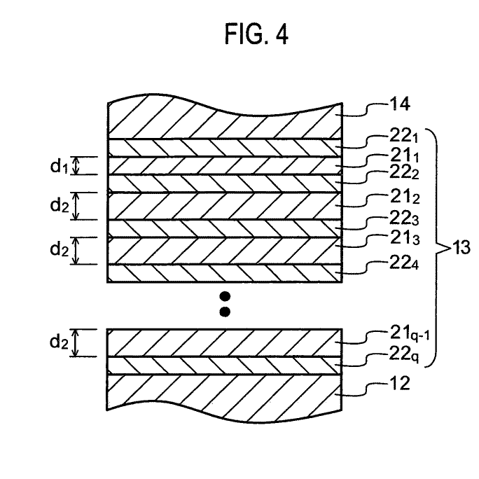

A semiconductor light-emitting device according to a second embodiment, which is a partial modification of the first embodiment described above, is explained below. As for the semiconductor light-emitting device according to the second embodiment, only a light-emitting layer different from that according to the first embodiment is explained. FIG. 4 is a cross-sectional view of the light-emitting layer according to the second embodiment.

As shown in FIG. 4, in the light-emitting layer 13 of the semiconductor light-emitting device 1 according to the second embodiment, a well layer (corresponding to a first well layer in claims 10) 21₁ closest to the p-type semiconductor layer 14 is a layer for emitting a blue light having a wavelength of about 420 nm to about 470 nm. The well layer 21₁ is made of undoped Inₓ₁Ga₁₋ₓ₁N. The well layer 21₁ is constituted such that the In ratio X₁ in InGaN constituting the well layer 21₁ satisfies 0.05≦X₁<0.2. A thickness d₁ of the well layer 21₁ is set to about 2 nm to about 3 nm so as to be able to produce a quantum size effect.

A well layer (corresponding to a second well layer in claims 10) 21₂ second closest to the p-type semiconductor layer 14 is a layer for emitting a green light (or a yellow light) having a wavelength of about 520 nm to about 650 nm. The well layer 21₂ is constituted such that the In ratio X₂ in InGaN constituting the well layer 21₂ satisfies 0.2≦X₁≦0.3. A thickness d₂ of the well layer 21₂ is set to about 3 nm to about 10 nm larger than the thickness d₁ of the well layer 21₁.

In this way, in the semiconductor light-emitting device 1 according to the second embodiment, the thickness d₁ of the well layer 21₁ is set smaller than the thickness d₂ of the well layer 21₂ so as to make the quantum size effect produced in the well layer 21₁ greater than that produced in the well layer 21₂. It is thereby possible to shift the wavelength of the light emitted from the well layer 21₁ to be closer to a short wavelength-side than that of the light emitted from the well layer 21₂.

Other well layers 21ₙ (3≦n≦q−1) are made of InGaN having the same thickness d₂ as that of the well layer 21₂.

Each barrier layer 22ₘ is formed between the two well layers 21ₙ. The barrier layer 22ₘ is made of undoped GaN having a thickness equal to or smaller than about 20 nm, preferably about 12 nm to about 16 nm at which thickness the barrier layer 22ₘ can transmit a green light from the second well layer 21₂.

An operation performed by the semiconductor light-emitting device 1 according to the second embodiment is described next with reference to FIG. 3.

First, when a forward voltage is applied to between the n-side electrode 4 and the p-side electrode 5, electrons are injected from the n-side electrode 4 into the semiconductor layer 3, and holes are injected from the p-side electrode 5 into the semiconductor layer 3. As shown in FIG. 3, the electrons injected from the n-side electrode 4 into the n-type semiconductor layer 12 can reach even each well layer 21₁ farthest from the n-type semiconductor layer 12 because of a high mobility. On the other hand, the holes injected from the p-side electrode 5 into the p-type semiconductor layer 14 are low in mobility. Therefore, most of the holes are trapped in the well layers 21₁ and 21₂ closer to the p-type semiconductor layer 14.

As a result, recombination of electrons and holes is sufficiently carried out in the well layer 21₁ where the electrons and holes are sufficiently trapped. Note that the well layer 21₁ emits the blue light L_{b} since the In ratio of the well layer 21₁ is higher than that of the well layer 21₂ and the well layer 21₁ is formed to have the smaller thickness than that of the well layer 21₂ so as to produce a greater quantum size effect. The blue light L_{b} emitted from the well layer 21₁ transmits through the barrier layer 22₁ and the p-type semiconductor layer 14 and then irradiated to outside.

Moreover, recombination of electrons and holes is sufficiently carried out in the well layer 21₂ where the electrons and holes are sufficiently trapped. Note that the well layer 21₂ produces a smaller quantum size effect than that of the well layer 21₁ and emits the green light L_{g} larger in wavelength than the blue light L_{b} since the In ratio of the well layer 21₂ is higher than that of the well layer 21₁ and the well layer 21₂ is formed to have the larger thickness than that of the well layer 21₁. The green light L_{g} emitted from the well layer 21₂ transmits through thin barrier layers 22₁ and 22₂ each having a thickness equal to or smaller than about 20 nm. The green light L_{g} having transmitted the barrier layers 22₁ and 22₂ transmits through the p-type semiconductor layer 14 and then irradiated to the outside.

On the other hand, the well layers 21ₙ (3≦n) far from the p-type semiconductor layer 14 do not emit the green light L_{g} so much, since the holes are hardly trapped in the well layers 21ₙ (3≦n).

As a result, the blue light L_{b} and the green light L_{g} are sufficiently irradiated by the well layers 21₁ and 21₂ from the semiconductor light-emitting device 1 to the outside.

A method for manufacturing the semiconductor light-emitting device 1 according to the second embodiment described above is explained next. In the method for manufacturing the semiconductor light-emitting device 1 according to the second embodiment, only a method for manufacturing the light-emitting layer 13 different from that according to the first embodiment is explained.

First, in a state of setting a growth temperature to about 690° C., TMG gas and ammonium gas are supplied using carrier gas, thereby forming a barrier layer 22_{q} made of undoped GaN on the n-type semiconductor layer 12. Thereafter, in a state of keeping the growth temperature to about 690° C., trimethylindium (hereinafter, TMI) gas, the TMG gas, and the ammonium gas are supplied using carrier gas while observing the state by a pyrometer (infrared ray), thereby forming the well layer 21_{q-1} made of undoped Inₓ₂Ga₁₋ₓ₂N (0.2≦X₂≦0.3) having a thickness of about 3 nm to about 10 nm on the barrier layer 22_{q}. Thereafter, the barrier layer 22₂ to the well layer 21₂ and the barrier layer 22ₘ to the well layer 21ₙ are alternately formed under the same conditions. Thereafter, in a state of setting the growth temperature to about 760° C., a growth time is set shorter than that of the other well layers 21ₙ (n≦2), thereby forming the well layer 21₁ made of undoped Inₓ₁Ga₁₋ₓ₁N (0.05≦X₁<0.2) thinner than the other well layers 21ₙ, that is, having a thickness of about 2 nm to about 3 nm. Finally, by forming the barrier layer 22₁, the light-emitting layer 13 is completed.

As described above, in the semiconductor light-emitting device 1 according to the second embodiment, the thickness of the well layer 21₁ is set different from those of the well layers 21ₙ (n≧2), thereby changing magnitudes of the quantum size effects acting on the well layers. By this configuration, the well layer 21₁ emits the blue light whereas the well layers 21ₙ (n≧2) other than the well layer 21₁ emit the green light. In this way, the semiconductor light-emitting device 1 according to the second embodiment changes wavelengths of lights to be emitted not only by the In ratios in the InGaN but also the thicknesses of the well layers 21ₙ (n≦1) easily controllable by the growth time or the like while being observed by the pyrometer or the like in manufacturing processes. Therefore, it is possible to set a wavelength of each light to be emitted to a desired wavelength easily and accurately.

Further, in the semiconductor light-emitting device 1 according to the second embodiment, the thickness d₁ of the well layer 21₁ closer to the p-type semiconductor layer 14 is set different from the thickness d₂ of the well layer 21₂. In this way, by setting the thicknesses of the well layers 21₁ and 21₂ that even holes having low mobility can easily reach different from each other, it is possible to sufficiently emit lights of different colors (a blue light and a green light).

Further, in the semiconductor light-emitting device 1 according to the second embodiment, the well layer 21₁ having a wider band gap is formed to be closer to the p-type semiconductor layer 14, that is, closer to the side to which holes are supplied than the well layer 21₂. In this way, by forming the well layer 21₁ where it is difficult to trap the holes to be closer to the p-type semiconductor layer 14, the number of holes reaching up to the well layer 21₂ can be further increased, and thus an emission intensity in the well layer 21₂ can be further improved.

Further, in the semiconductor light-emitting device 1 according to the second embodiment, the barrier layer 22₂ between the well layers 21₁ and 21₂ is constituted to have a thickness equal to or smaller than about 20 nm, preferably about 12 nm to about 16 nm, at which the barrier layer 22₂ can transmit the green light emitted from the well layer 21₂. The green light can be thereby irradiated to the outside.

Further, in the semiconductor light-emitting device 1 according to the second embodiment, the growth temperature of the p-type semiconductor layer 14 is set to be equal to or lower than about 850° C. By this configuration, degradation in crystallinity of the InGaN constituting the well layers 21ₙ, particularly the well layers 21ₙ (n≧2) that emit the green light can be suppressed at the time of forming the p-type semiconductor layer 14. Therefore, it is possible to irradiate more green lights to the outside.

Further, the semiconductor light-emitting device 1 according to the second embodiment can emit lights of two different colors without using a fluorescent body for which it is difficult to control an addition amount and which tends to be degraded. Therefore, it is possible to easily control light amounts of the lights of different colors to suppress tint irregularities, and suppress degradation to ensure high reliability. Also, it is possible to realize an intermediate color (a pastel color) that cannot be expressed by the fluorescent body.

### EXPERIMENTS

Examples carried out to prove effects of the semiconductor light-emitting device 1 described above are examined next.

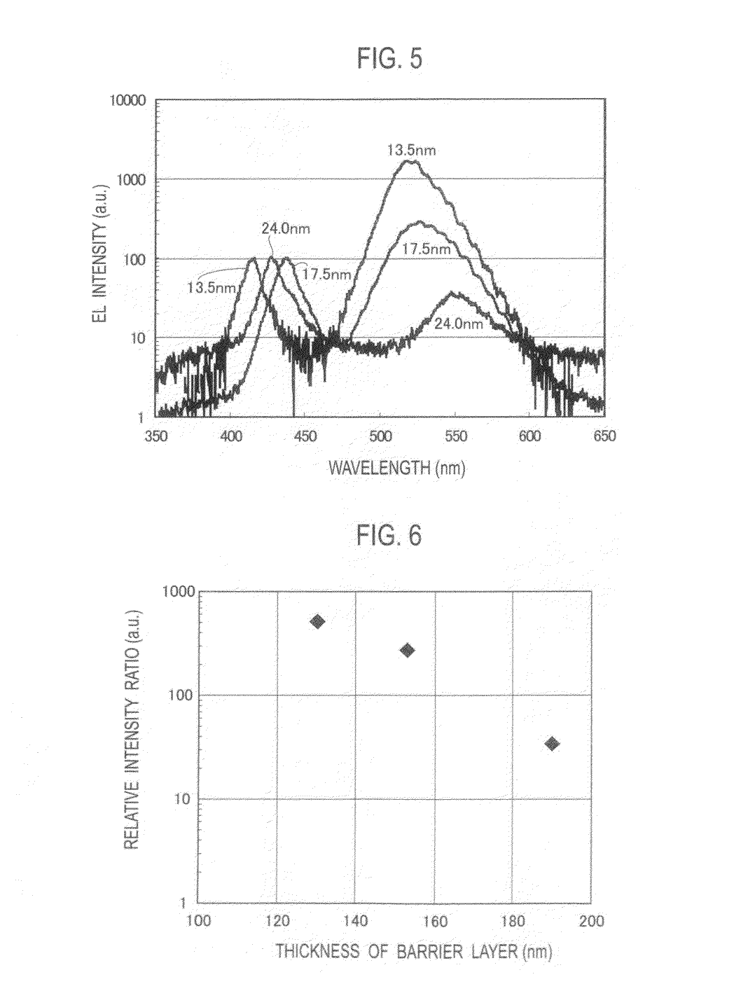

First, the relationship between the thickness of the barrier layer and an electroluminescence (hereinafter, EL) intensity of the light irradiated to the outside is described first with reference to the drawings. FIG. 5 is a graph showing a comparison of emission spectrums when the thickness of a barrier layer is changed. In FIG. 5, a horizontal axis indicates wavelength and a vertical axis indicates EL intensity. A suffix lateral of each spectrum indicates the thickness of the barrier layer 22₂. FIG. 6 is a chart showing a comparison of relative intensity ratios when the thickness of the barrier layer is changed. In FIG. 6, a horizontal axis indicates the thickness of the barrier layer 22₂ and a vertical axis indicates relative intensity ratio. The relative intensity ratio means an EL intensity ratio of the green light when an EL intensity of the blue light is assumed as 100.

As shown in FIGS. 5 and 6, when the thickness of the barrier layer is made smaller to 24.0 nm, 17.5 nm, and 13.5 nm, the EL intensity of the green light L_{g} emitted from the well layer 21₂ second closest to the p-type semiconductor layer 14 increases, while the EL intensity of the green light L_{b} emitted from the well layer 21₁ closest to the p-type semiconductor layer 14 is constant. It is also clear that the EL intensity of the green light L_{g} becomes higher than that of the blue light L_{b} as the barrier layer is thinner. This indicates that the light amount of the green light L_{g} irradiated to the outside can be controlled by changing the thickness of the barrier layer 22₂. As a result, it is evident that tint of an intermediate color (a pastel color) between the blue light L_{b} and the green light L_{g} can be easily controlled by the thickness of the barrier layer 22₂.

Furthermore, considering that the well layer 21₂ that emits the green light L_{g} is formed at a position farther from the p-type semiconductor layer 14 than the well layer 21₁ that emits the blue light L_{b}, and that an energy level is higher in the well layer 21₂ than the well layer 21₁, it can be easily estimated that more holes are injected into the well layer 21₂ and the green light L_{g} is more intense than the blue light L_{b} when the barrier layer 22ₘ is thinner than about 14 nm.

Further, considering that human visibility is stronger to the green light L_{g}, a rate of the green light L_{g} included in emission spectrums of the lights irradiated from the semiconductor light-emitting device 1 increases by setting the thickness of the barrier layer 22₂ to be equal to or smaller than about 16 nm, preferably about 14 nm and therefore, it is understood that human eyes recognize the light as a white light.

Therefore, when the semiconductor light-emitting device 1 described above is applied to a white semiconductor light-emitting device, it suffices to set thicknesses of the barrier layers 22ₘ, at least the thickness of the barrier layer 22₂ to be equal to or smaller than about 16 nm, preferably about 14 nm. In addition, even when lights other than the white light are desired, it is possible to adjust tint of the blue light and green light and irradiate various colors by changing the thickness of the barrier layer 22₂ and thereby adjusting an injection amount of the holes into the well layer 21₂.

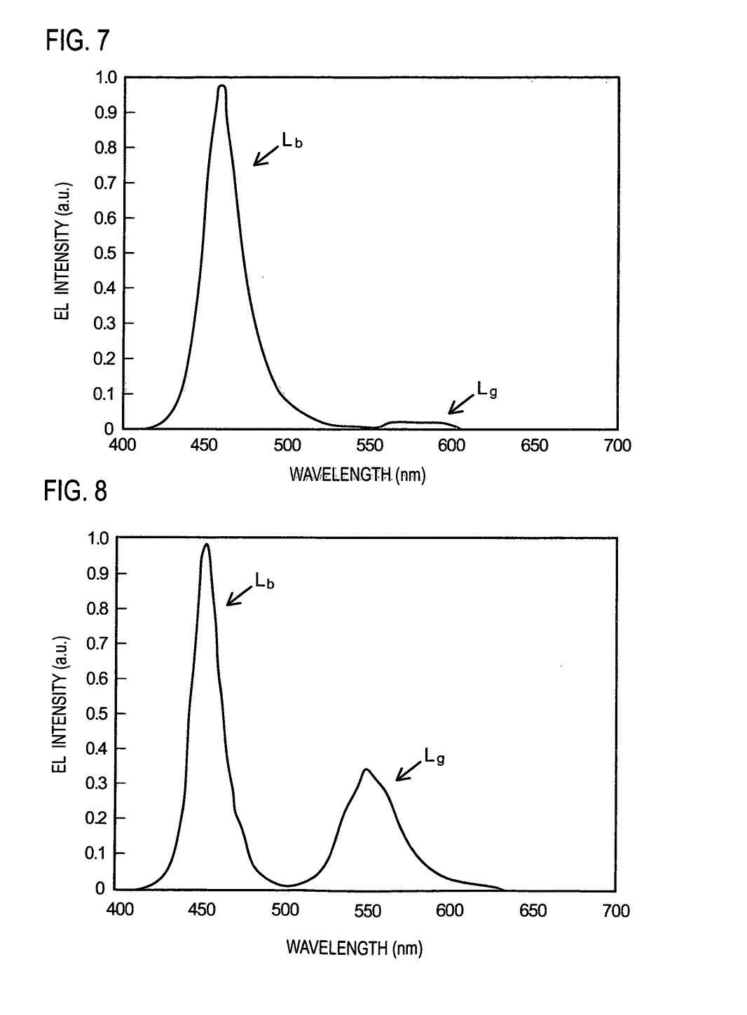

The relationship between a growth temperature and the spectrum of light irradiated to the outside when the p-type semiconductor layer 14 is formed is explained next with reference to the drawings. Note that a spectrum shown in FIG. 7 is an example of an EL intensity spectrum when the p-type semiconductor layer is formed at the growth temperature of about 1010° C., and that a spectrum shown in FIG. 8 is an example of an EL intensity spectrum when the p-type semiconductor layer is formed at the growth temperature of about 850° C.

As shown in FIG. 7, as is obvious from the EL intensity spectrum of the semiconductor light-emitting device 1 in which the p-type semiconductor layer 14 made of p-type GaN is grown in a state of setting the growth temperature to about 1010° C., most of the lights irradiated to the outside are the blue light L_{b} and the lights hardly include the green light L_{g}. On the other hand, as shown in FIG. 8, as is obvious from the EL intensity spectrum of the semiconductor light-emitting device 1 in which the p-type semiconductor layer 14 made of p-type GaN is grown in a state of setting the growth temperature to about 850° C., the green light L_{g} having the EL intensity about one-third of that of the blue light L_{b} is irradiated to the outside.

This reason for the above facts is considered as follows. By forming the p-type semiconductor layer 14 at the growth temperature of about 1010° C. after growing the light-emitting layer 13, the crystallinity of the InGaN constituting the well layers 21ₙ, particularly the well layers 21ₙ (n≧2) that emits the green light L_{g} having the high In ratio was degraded. On the other hand, when the p-type semiconductor layer 14 was formed at the growth temperature of about 850° C., degradation in the well layers 21ₙ (n≧2) was suppressed.

While embodiments of the present invention have been described above, the invention is not limited to the embodiments described in this specification. The scope of the invention is limited by the descriptions of the appended claims and by the equivalent range of the claims. A modification mode, which is a partial modification of the above embodiments, is described below.

For example, in the above embodiments, the present invention is applied to the semiconductor light-emitting device that emits a blue light and a green light (or a yellow light). Alternatively, the present invention can be applied to a semiconductor light-emitting device that can emit lights of two or more different colors including a red light or the like other than the above-mentioned lights.

Furthermore, materials constituting the respective layers described in the above embodiments can be appropriately changed. For example, the well layer can be constituted by an InGaN-based semiconductor such as AlInGaN other than InGaN. The barrier layer can be constituted by a GaN-based semiconductor such as AlGaN other than GaN.

Further, in the above embodiments, the In ratio in the InGaN constituting each well layer is changed by changing the growth temperature. Alternatively, the In ratio can be changed by changing a flow rate of In material gas (TMI gas).

Moreover, in the above embodiments, the well layer that emits a short-wavelength light (a blue light) is formed to be closer to the p-type semiconductor layer than the well layer that emits a long-wavelength light (a green light). Alternatively, the well layer that emits the long-wavelength light can be formed to be closer to the p-type semiconductor layer.

Furthermore, in the above embodiments, the third closest well layer to the farthest well layer to the p-type semiconductor layer are formed out of the same constitution as that of the second well layer. Alternatively, the well layers can be constituted to have different band gaps.

Further, in the above embodiments, the first well layer and the second well layer are formed to be equal in thickness. Alternatively, the first well layer can be formed to have a small thickness enough to produce the quantum size effect and to have a smaller thickness than that of the second well layer. With this arrangement, it is possible to control the wavelengths not only by the In ratios in the InGaN but also by the thicknesses of the well layers.

Moreover, the thicknesses of the respective layers described in the above embodiments can be appropriately changed. For example, the thickness of the thinnest well layer is not limited to a specific value as long as the thickness is large enough (equal to or smaller than about 10 nm) to produce the quantum size effect.

Furthermore, in the above embodiments, the thicknesses of the well layers are changed by changing a growth time. Alternatively, the thicknesses can be changed by changing flow rates of material gasses (TMI gas, TMG gas, and ammonium gas).

Further, in the above embodiments, the third closest well layer to the farthest well layer to the p-type semiconductor layer are formed out of the same constitution as that of the second well layer. Alternatively, the well layers can be constituted to have different band gaps. By way of example, a well layer that can emit a short-wavelength light (such as a blue light) and a well layer that can emit a long-wavelength light (such as a green light) can be alternately and periodically formed. In another alternative, after forming a plurality of well layers that can a short-wavelength light (such as a blue light), a plurality of well layers that can emit a long-wavelength light (such as a green light) can be formed.

### INDUSTRIAL APPLICABILITY

According to the present invention, the In ratio X₁ in the first well layer made of the InGaN-based semiconductor is set different from the In ratio X₂ in the second well layer made of the InGaN-based semiconductor. By so constituting the first well layer and the second well layer that holes can easily reach, the present invention can sufficiently emit lights of two different colors.

According to the present invention, the second well layer is formed thicker than the first well layer, and therefore the wavelength of the light emitted from the first well layer can be set smaller than that of the light emitted from the second well layer. In this way, the present invention can easily control the wavelengths of two or more lights since the wavelengths of the emitted lights are controlled not only by the In ratios in the InGaN but also the thicknesses of the well layers easily controllable in the manufacturing process. Furthermore, the present invention can control tint relatively easily by changing the thicknesses of the well layers and the barrier layers.

1. A semiconductor light-emitting device comprising: a p-type semiconductor layer; and a light-emitting layer including a plurality of well layers made of an InGaN-based semiconductor and a barrier layer made of a GaN-based semiconductor and formed between the respective well layers, wherein
an In ratio X₁ in an Inₓ₁Ga₁₋ₓ₁N-based semiconductor comprising a first well layer closest to the p-type semiconductor layer differs from an In ratio X₂ in an Inₓ₂Ga₁₋ₓ₂N-based semiconductor comprising a second well layer second closest to the p-type semiconductor layer.

2. The semiconductor light-emitting device according to claim 1, wherein the In ratio X₁ is lower than the In ratio X₂.

3. The semiconductor light-emitting device according to claim 1, wherein the In ratio X₁ satisfies X₁<0.2 and the In ratio X₂ satisfies X₂≧0.2.

4. The semiconductor light-emitting device according to claim 1, wherein a barrier layer between the first well layer and the second well layer has a thickness enough to be able to transmit a light emitted from the second well layer.

5. The semiconductor light-emitting device according to claim 1, wherein a barrier layer between the first well layer and the second well layer has a thickness equal to or smaller than 20 nm.

6. The semiconductor light-emitting device according to claim 1, wherein the first well layer emits a blue light and the second well layer emits a light having a peak between a green light and a yellow light.

7. The semiconductor light-emitting device according to claim 1, wherein a thickness of the first well layer is smaller than a thickness of the second well layer and smaller than a thickness enough to produce a quantum size effect.

8. A semiconductor light-emitting device comprising: a p-type semiconductor layer; and a light-emitting layer including a plurality of well layers made of an InGaN-based semiconductor and a barrier layer made of a GaN-based semiconductor and formed between the respective well layers, wherein
an In ratio X₁ in an Inₓ₁Ga₁₋ₓ₁N-based semiconductor comprising a first well layer closest to the p-type semiconductor layer satisfies 0.05≦X₁<0.2,
an In ratio X₂ in an Inₓ₂Ga₁₋ₓ₂N-based semiconductor comprising a second well layer second closest to the p-type semiconductor layer satisfies 0.2≦X₂≦0.3, and
a thickness of a barrier layer between the first well layer and the second well layer is 12 nm to 16 nm.

9. A method for manufacturing a semiconductor light-emitting device comprising: a p-type semiconductor layer made of a p-type GaN-based semiconductor; and a light-emitting layer including a plurality of well layers made of an InGaN-based semiconductor, wherein an In ratio X₁ in an Inₓ₁Ga₁₋ₓ₁N-based semiconductor comprising a first well layer closest to the p-type semiconductor layer differs from an In ratio X₂ in an Inₓ₂Ga₁₋ₓ₂N-based semiconductor comprising a second well layer second closest to the p-type semiconductor layer, the method comprising:
a light-emitting layer forming step of forming a light-emitting layer including the first well layer and the second well layer; and
a p-type semiconductor layer forming step of growing the p-type semiconductor layer at a growth temperature equal to or lower than 850° C. after the light-emitting layer forming step.

10. A semiconductor light-emitting device comprising: a p-type semiconductor layer; and a light-emitting layer including a plurality of well layers made of an InGaN-based semiconductor and a barrier layer formed between the respective well layers, wherein
the light-emitting layer includes a first well layer and a second well layer thicker than the first well layer and emits a light having a wavelength different from a wavelength of a light emitted from the first well layer,
the first well layer is arranged at a closer position to the p-type semiconductor layer than the second well layer,
a barrier layer between the first well layer and the second well layer is constituted to have a thickness enough to be able to transmit a light emitted from the second well layer.

11. The semiconductor light-emitting device according to claim 10, wherein the first well layer is constituted to have a thickness enough to produce a quantum size effect.

12. The semiconductor light-emitting device according to claim 10, wherein the thickness of the barrier layer between the first well layer and the second well layer is 12 nm to 16 nm.

13. The semiconductor light-emitting device according to claim 10, wherein the first well layer is formed at a closest position to the p-type semiconductor layer among the well layers, and the second well layer is formed at a second closest position to the p-type semiconductor layer among the well layers.

14. The semiconductor light-emitting device according to claim 10, wherein the first well layer emits a shorter-wavelength light than the light emitted from the second well layer.

15. The semiconductor light-emitting device according to claim 10, wherein the second well layer is higher in an In ratio in the InGaN-based semiconductor than the first well layer.

16. The semiconductor light-emitting device according to claim 10, wherein the first well layer emits a blue light and the second well layer emits a light having a peak between a green light and a yellow light.

17. A semiconductor light-emitting device comprising: a p-type semiconductor layer; and a light-emitting layer including a plurality of well layers made of an InGaN-based semiconductor and a barrier layer made of a GaN-based semiconductor and formed between the respective well layers, wherein
a thickness d₁ of a first well layer closest to the p-type semiconductor layer satisfies 2 nm≦d₁≦3 nm,
a thickness d₂ of a second well layer second closest to the p-type semiconductor layer satisfies 3 nm≦d₁≦10 nm, and
a thickness of a barrier layer between the first well layer and the second well layer is 12 nm to 16 nm.

18. A method for manufacturing a semiconductor light-emitting device comprising: a p-type semiconductor layer made of a p-type GaN-based semiconductor; and a light-emitting layer including a plurality of well layers including a first well layer made of an InGaN-based semiconductor and a second well layer thicker than the first well layer, and a barrier layer capable of transmitting a light emitted from the second well layer, the method comprising:
a light-emitting layer forming step of forming the light-emitting layer including the first well layer and the second well layer; and
a p-type semiconductor layer forming step of growing the p-type semiconductor layer at a growth temperature equal to or lower than 850° C. after the light-emitting layer forming step.
